(19) United States
(12) Patent Application Publication
(10) Pub. No.: US 2013/0049843 A1
(43) Pub. Date: Feb. 28, 2013

(54) REVERSE CONDUCTION MODE SELF TURN-OFF GATE DRIVER

(71) Applicants: Mari Curbelo Alvaro Jorge, Unterschleissheim (DE); Thomas Zoels, Unterschleissheim (DE)

(72) Inventors: Mari Curbelo Alvaro Jorge, Unterschleissheim (DE); Thomas Zoels, Unterschleissheim (DE)

(21) Appl. No.: 13/219,219

(22) Filed: Aug. 26, 2011

(51) Int. Cl. H03K 17/72

(52) U.S. Cl. 327/438

(57) ABSTRACT

There is provided a power electronic module that includes a power switch module and a drive circuit operatively coupled to the power switch module. The drive circuit is configured to enable and disable a forward conduction mode operation of the switch module. The drive circuit disables forward conduction mode operation of the power switch module when the power switch module is operating in reverse conduction mode.

### BACKGROUND

1. Technical Field

Exemplary embodiments of the invention relate generally to a system and method for improving the reliability and efficiency of an electronic device such as an inverter. Moreover, such exemplary embodiments may relate to an improved drive circuit for voltage controlled power switches.

2. Discussion of Art

Power electronic devices may be used in a wide variety of systems and devices for delivering power to a load. For example, traction vehicles such as locomotives, employ electric traction motors for driving wheels of the vehicles. In some of these vehicles, the motors are alternating current (AC) motors whose speed and power are controlled by varying the frequency and the voltage of AC electric power supplied to the field windings of the motors. Commonly, the electric power is supplied at some point in the vehicle system as DC power and is thereafter converted to AC power of controlled frequency and voltage amplitude by a power electronic device such as an inverter. Power electronic devices may also be used in a variety of other applications, such as industrial power electronics, and stationary power conversion, among others. The power electronic device may include a set of semiconductor-based voltage controlled power switches (VCPS) such as reverse blocking insulated gate bipolar transistors (IGBTs), reverse conducting insulated gate bipolar transistors (RC-IGBTs), bi-mode insulated gate transistors (BIGTs), and the like. RC-IGBTs and BIGTs are reverse conductive power switches (RCPSs) which form a subgroup within the VCPS.

### SUMMARY

Briefly, in accordance with an exemplary embodiment of the invention, there is provided a power electronic module that includes a power switch module and a drive circuit operatively coupled to the power switch module. The exemplary drive circuit is configured to enable and disable a forward conduction mode operation of the switch module. The drive circuit disables forward conduction mode operation of the power switch module when the power switch module is operating in reverse conduction mode.

In another exemplary embodiment of the invention, there is provided a power system for a vehicle. The exemplary power system includes a first power switch module coupled to a DC rail voltage and configured to switch on and off in an alternation with a second switch module to produce an output AC waveform. The exemplary power system also includes a drive circuit operatively coupled to the first switch module and configured to enable and disable a forward conduction mode operation of the first switch module. The drive circuit disables forward conduction mode operation of the first power switch module when the first power switch module is operating in reverse conduction mode.

In another exemplary embodiment of the invention, there is provided a method comprising receiving a command from a control circuit to activate a forward conduction mode operation of a power switch module. The exemplary method also includes determining whether the power switch module is operating in reverse conduction mode. If the power switch module is operating in reverse conduction mode, forward conduction mode operation of the power switch module is disabled. If the power switch module is not operating in reverse conduction mode, forward conduction mode operation of the power switch module is enabled.

### DRAWINGS

These and other features, aspects, and advantages of the invention will become better understood when the following detailed description is read with reference to the accompanying drawings in which like characters represent like parts throughout the drawings, wherein:

FIG. 1 is a block diagram of a diesel-electric locomotive that may employ an inverter in accordance with embodiments;

FIG. 2 is a block diagram of a power system in accordance with embodiments;

FIG. 3 is a block diagram of one leg of an IGBT inverter in accordance with embodiments;

FIG. 4 is a block diagram of one leg of a BIGT inverter in accordance with embodiments;

FIG. 5 is a graph of a switching scheme for a voltage controlled power switch (VCPS) two level (2L) inverter;

FIG. 6 is a graph of an exemplary switching scheme that may be employed in a 2L inverter, in accordance with embodiments;

FIG. 7 is a block diagram of an example of a drive circuit in accordance with embodiments;

FIG. 8 is a block diagram of an example of a drive circuit in accordance with embodiments;

FIG. 9 is a block diagram of an example of a drive circuit in accordance with embodiments and

FIG. 10 is a process flow diagram summarizing a method of operating an inverter module in accordance with embodiments.

### DETAILED DESCRIPTION

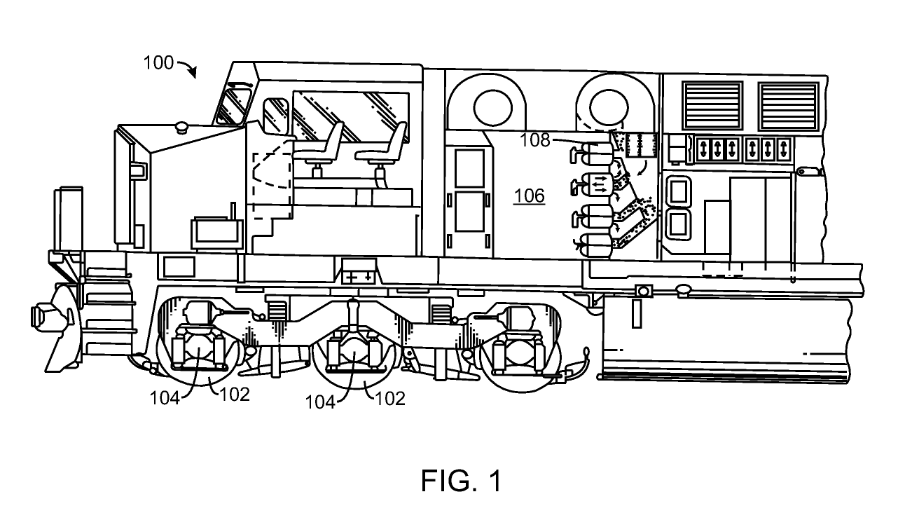

FIG. 1 is a block diagram of a diesel-electric locomotive that may employ an inverter in accordance with embodiments. The locomotive, which is shown in a simplified, partial cross-sectional view, is generally referred to by the reference number 100. A plurality of traction motors, not visible in FIG. 1, are located behind drive wheels 102 and coupled in a driving relationship to axles 104. A plurality of auxiliary motors, not visible in FIG. 1, are located in various locations on the locomotive, and coupled with various auxiliary loads like blowers or radiator fans. The motors may be alternating current (AC) electric motors. As explained in detail below, the locomotive 100 may include a plurality of electrical inverter circuits for controlling electrical power to the motors.

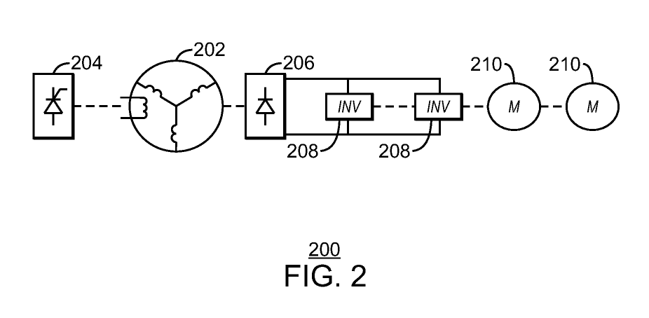

FIG. 2 is a block diagram of a power system in accordance with embodiments. The power system, which is generally referred to by the reference number 200, may be used to control AC power to a load. The power system 200 may include an alternator 202 driven by an on-board internal combustion engine such as a diesel engine (not shown). The power output of the alternator 202 is regulated by field excitation control indicated by a field control 204. Electrical power from alternator 202 is rectified by a rectifier 206, and coupled to one or more inverters 208. The inverters 208 may use high-power semiconductor-based voltage controlled power switches (VCPSs) to convert the DC power to AC power with variable frequency and variable voltage amplitude for application to one or more AC motors 210. Although two motors are shown, the locomotive may include four to six AC electric motors may be employed, each controlled by an individual inverter.

Referring again to FIG. 1, electrical power circuits are at least partially located in an equipment compartment 106. The control electronics for the inverters 208 and the field control 204 as well as other electronic components may be disposed on circuit boards held in racks in the equipment compartment 106. Within the equipment compartment 106, the VCPSs used in the power conversion may be mounted to air-cooled heat sinks 108. The inverter circuits in the power system of FIG. 2 are but one example of a power electronic device in accordance with the techniques disclosed herein. It will be appreciated that embodiments of the present techniques may be employed in any suitable power electronic device that delivers electrical power to a load, including industrial power electronics, and stationary power conversion, among others.

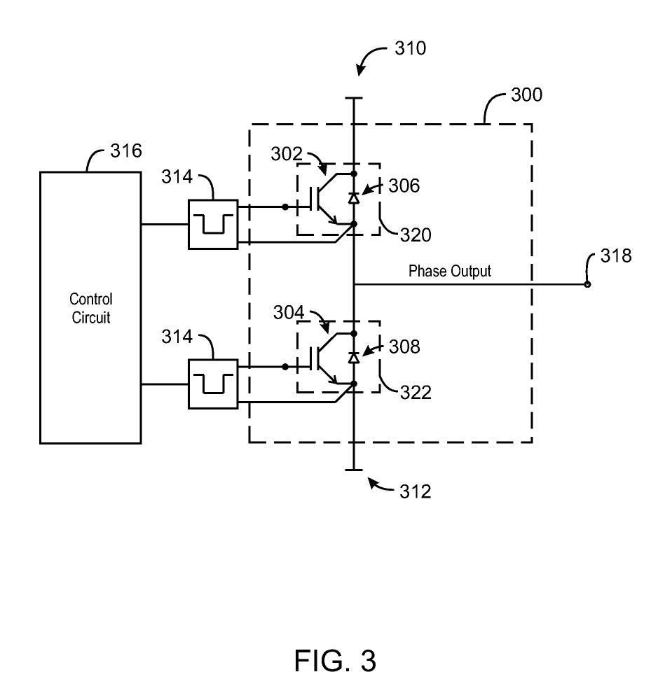

As noted above, the inverters 208 used to generate the AC waveform may include VCPSs. A VCPS employs at least two power terminals and one or two control terminals. There are different naming conventions for the power terminals depending on the VCPS type, examples are anode and cathode or collector and emitter. When positive current through these power terminals is conducted from anode to cathode or from collector to emitter it is referred to as forward conduction. When positive current through the power terminals is conducted from cathode to anode or from emitter to collector it is referred to as reverse conduction. The same holds for the voltage across the power terminals where a positive voltage from anode to cathode or from collector to emitter is referred to as forward polarization and a positive voltage from cathode to anode or from emitter to collector is referred to as reverse polarization. In accordance with embodiments, the drive circuitry used to drive the switches may be configured to determine the polarity of the voltage across or the current through the power terminals of the switch. The drive signal produced by the drive circuitry may depend, at least in part, on the detected polarity. Depending on the type of switch used in the inverter, various benefits may be realized by controlling the drive signal based on the detected polarity. FIG. 3 is a block diagram of one leg of an IGBT inverter in accordance with embodiments. As shown in FIG. 3, the inverter leg 300 includes a pair of IGBTs referred to herein as upper IGBT 302 and lower IGBT 304. A diode, referred to herein as upper diode 306, is disposed in anti-parallel across the collector and emitter of the upper IGBT 302. A diode, referred to herein as lower diode 308, is disposed in anti-parallel across the collector and emitter of the lower IGBT 304. Each IGBT and corresponding anti-parallel diode (for example, upper IGBT 302 and upper diode 306) form a unit referred to herein as an IGBT module 320 and 322, which is one example of a power switch module with a reverse blocking power switch (RBPS module). The diodes 306 and 308 provide a conductive path for freewheeling current, which is current that is generated, due to the inductance of the circuit and the load, when a current-conducting switch is turned off. The upper diode 306 provides a conductive path for freewheeling current that may result when the lower IGBT 304 is switched off. The lower diode 308 provides a conductive path for freewheeling current that may result when the upper IGBT 302 is switched off. The upper IGBT 302 and lower IGBT 304 are disposed in series between an upper rail voltage 310 and lower rail voltage 312.

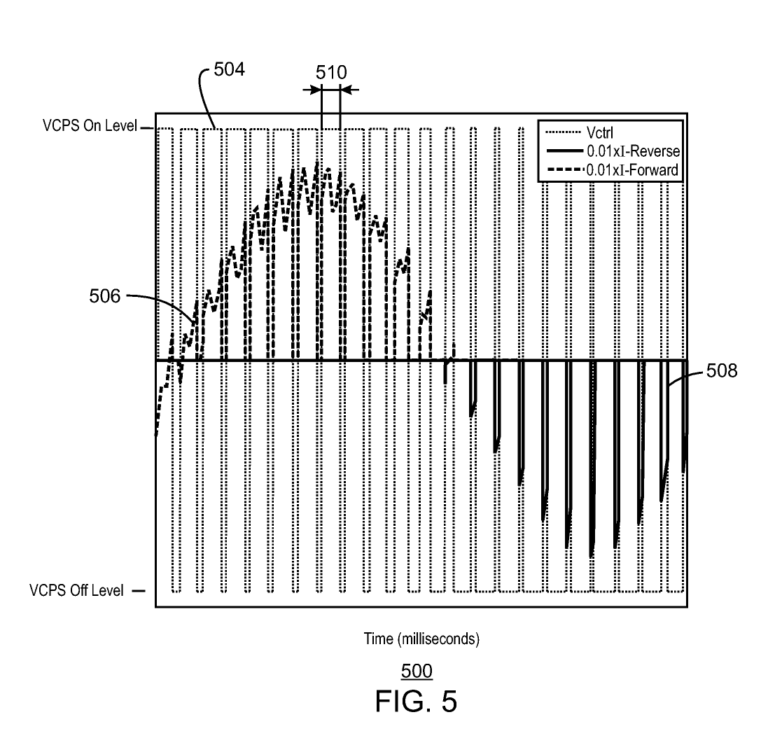

Each IGBT 302 and 304 is driven by a gate driver 314 operatively coupled to the gate of the corresponding IGBT 302 and 304. A control circuit 316 may be operatively coupled to the gate drivers 314 to coordinate the switching of the IGBTs 302 and 304. The control circuit 316 may cause the IGBTs 302 and 304 to pulse on and off in an alternating fashion to produce an AC waveform at the phase output 318. To prevent a short circuit between the upper rail voltage 310 and the lower rail voltage 312, the drive signals for the IGBTs 302 and 304 are coordinated so that the IGBTs are not both turned on at the same time. For example, a time delay may be imposed between the time that one IGBT is switched off and the time that the other IGBT is switched on. This time delay is referred to herein as an interlock time and may be approximately 20 to 30 micro seconds, for example. Although only one leg 300 is shown, it will be appreciated that the inverter module may include two, three, or more legs, each providing an output AC waveform for a particular phase. For example, three legs may be used to produce a three-phase AC output waveform. A standard switching scheme is described further in relation to FIG. 5.

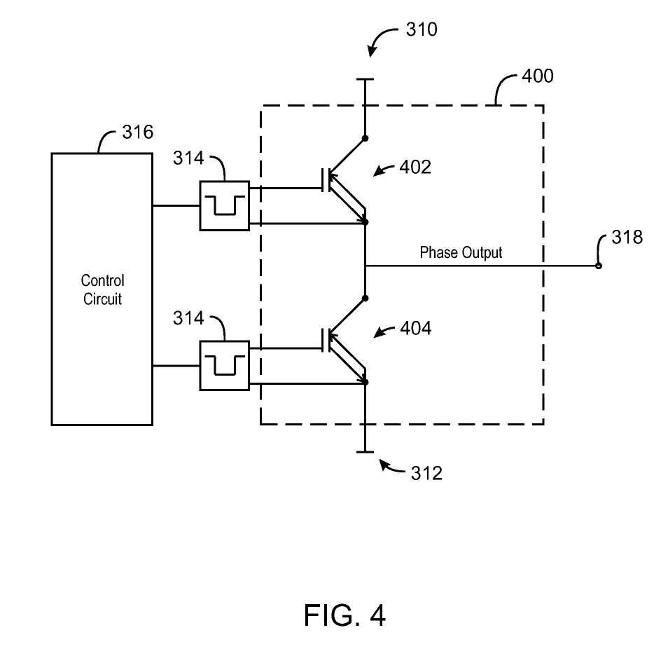

FIG. 4 is a block diagram of one leg of a BIGT inverter in accordance with embodiments. As shown in FIG. 4, the inverter leg 400 includes a pair of BIGTs, referred to herein as upper BIGT 402 and lower BIGT 404. Each BIGT 402 and 404 form a unit may be referred to herein as a BIGT module, which can operate in a forward conduction mode or a reverse conduction mode. Each BIGT 402 and 404 is an example of a power switch module with a reverse conducting power switch (RCPS module). As in the IGBT inverter of FIG. 3, each BIGT 402 and 404 is driven by a gate driver 314 operatively coupled to the gate of the corresponding BIGT 402 and 404. The gate driver 314 may provide one voltage level to enable the forward conduction mode operation of the BIGTs 402 and 404 and another voltage level to disable the forward conduction mode operation of the BIGTs 402 and 404. In embodiments, a gate voltage of +15 Volts will enable the forward conduction mode operation and a gate voltage of −15 Volts will disable forward conduction mode operation.

The reverse conduction mode operation of the BIGTs 402 and 404 is determined by the polarity of the voltage across the emitter and collector of the BIGT 402 or 404. For example, the lower BIGT 404 will operate in reverse conduction mode if the voltage at the phase output 318 is lower than the voltage at the lower rail 312. When in reverse conduction mode, the BIGTs 402 and 404 provide a conductive path for freewheeling current that may result when the other BIGT in the leg 400 is switched off. The BIGTs 402 and 404 can operate in reverse conduction mode regardless of whether the gate voltage is positive or negative. During the reverse conduction mode operation of the lower BIGT 404, current is conducted from the lower rail 312 to the phase output 318.

The control circuit 316 may be operatively coupled to the gate driver 314 to coordinate the switching of the BIGTs 402 and 404. The control circuit 316 may cause the BIGTs 402 and 404 to pulse the forward conduction mode operation of the BIGTs 402 and 404 on and off in an alternating fashion to produce an AC waveform at the phase output 318. As described above in reference to FIG. 3, a time delay, referred to as the interlock time, is imposed between the time that one BIGT is switched off and the time that the other BIGT in the leg 400 is switched on. It will be appreciated that the BIGT inverter may also include two, three, or more legs, each providing an output AC waveform for a particular phase.

FIG. 5 is a graph of a switching scheme for an voltage controlled power switch (VCPS) inverter. In the case of an IGBT power switch module as shown in FIG. 3, FIG. 5 plots a gate drive signal, Vge, as it is applied to upper IGBT 302 of FIG. 3 and is superimposed over the resulting currents generated in the upper IGBT 302 an upper diode 306 that is disposed in anti-parallel to the upper IGBT 302. The gate drive signal, Vge, is represented by the dotted line 504. The IGBT current is represented by the dashed line 506. The diode current is represented by the solid line 508. The X-axis represents time. The Y-axis represents voltage with respect to the gate drive signal and current with respect to the IGBT and diode currents.

As shown in FIG. 5, the gate drive signal 504 causes the upper IGBT 302 to be pulsed on and off to produce an output wave from with an approximately sinusoidal waveform. Although not shown, the upper IGBT 302 may be pulsed on and off in alternation with the lower IGBT 304 to produce a complimentary AC waveform that adds to the phase output. The resulting output waveform is generated by controlling the pulse width 510 of the drive signal 504. FIG. 5 shows approximately one period of the resulting output waveform.

For purposes of the present discussion, when current through a power switch module is positive, the corresponding power switch module is referred to as operating in forward conduction mode. When the voltage across the power terminals of the power switch is polarized in forward direction and the current through the power switch module is about zero the power switch module is referred to as operating in blocking mode. When the voltage across the power terminals of the power switch module is polarized in the forward direction, the voltage across the control terminals determine if the power switch module is in forward conduction or blocking mode. The control voltage level for enabling forward conduction mode is referred to as turn on level. The control voltage level for disabling forward conduction mode is referred to as turn off level. It will be appreciated that the polarity of the current through the power switch module determines whether the switch module is in forward conduction mode or reverse conduction mode. For example, in the case of the lower IGBT module 322, if the current is flowing from the phase output 318 to the lower rail 312 (current positive), the lower IGBT module 322 is operating in forward conduction mode. If current is flowing from the lower rail 312 to the phase out 318 (current negative), the lower IGBT module 322 is operating in reverse conduction mode. It should be noted that, depending on the voltage across the collector and emitter of the switch module, the IGBT module may operate in reverse conduction mode even if forward conduction mode operation is enabled by the gate voltage applied to the IGBT.

During the first half of the period, the voltage across the power terminals of the power switch module is polarized in forward direction and it operates alternating in forward conduction mode and blocking mode depending on the control voltage level. For example, current through the lower IGBT 304 is positive when the gate voltage is at +15V, and drops to zero when the gate voltage changes to −15V. The upper diode 306 conducts the resulting freewheeling current (not shown). During the first half of the period, the current in the lower power switch module remains at zero. During the second half of the period, the lower power switch module operates alternating in reverse conduction mode and blocking mode. When the upper power switch module is switched off during the second half of the period, the lower power switch module goes into reverse conduction mode and conducts the current from the upper power switch module which has been switched off. The control voltage in the standard switching scheme of FIG. 5 is at turn on level even though the power switch module is in reverse conducting mode.

Problems can arise in the second half of the period, when the lower power switch module is conducting the freewheeling current. For example, in some circumstances, the upper power switch module may turn on improperly due to a spurious triggering or cosmic particle. If this occurs, a short circuit between the phase output 318 and the upper rail 310 voltage is induced, creating an intra-module commutation, which means that the current through the power switch module changes polarity. For example, with regard to the lower IGBT module in FIG. 3, the current commutates from the lower diode 308 to the lower IGBT 304. This change in polarity causes switch desaturation, which means that the voltage across the power terminals of the lower power switch module rises and can create an unusually high voltage stress on the lower diode during the transition between conduction mode and blocking mode of the diode where for short time a current is flowing in a direction from the cathode to the anode. This voltage stress may lead to failure of the lower diode 308 and lower switch module failure. The same situation could occur with respect to the upper power switch module if the lower power switch module is improperly turned on.

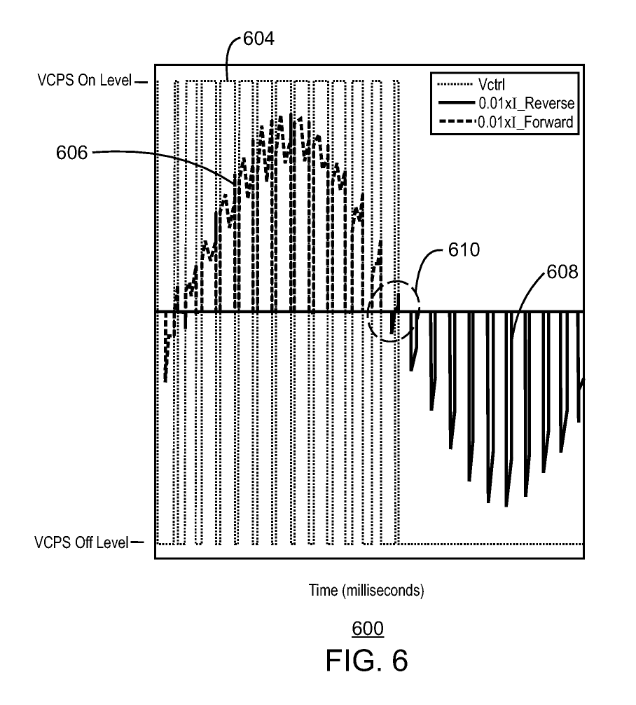

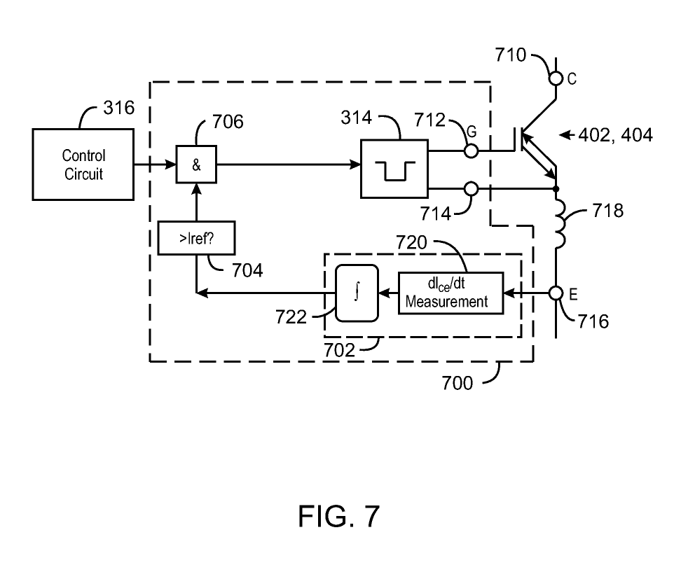

To avoid a short circuit, the drive circuits may be configured to keep the corresponding control voltage at turn off level depending on the polarity of the current through the power switch module. Referring to the lower power switch module of FIGS. 3 and 4 as an example, a drive circuit incorporating the gate driver 314 may be configured to determine the polarity of the current in the lower power switch module. If the current polarity indicates that the power switch module is in reverse conduction mode, the lower power switch module may be commanded by the gate driver 314 to remain off, even if the external trigger from the control circuit 316 is commanding the lower power switch module to turn on. In this way, a spurious triggering of the upper power switch module would not cause a short circuit, because the lower power switch module would be switched off. The drive circuit for the upper power switch module may be configured in the same manner. An exemplary switching scheme is described further in relation to FIG. 6. Exemplary drive circuit configurations are described further below with reference to FIGS. 7-9.

In the case of a reverse conductive power switch module (RCPS module) such as the BIGT switch modules of FIG. 4, FIG. 5 plots a gate drive signal, Vge, as it is applied to the lower BIGT 404 of FIG. 4 and is superimposed over the resulting currents generated in the lower IGBT 404. Power switch modules in general can operate in reverse conduction mode regardless of whether the control voltage is at turn on level or turn off level. However, in some embodiments of the RCPS module like the BIGT module, when the RCPS module is operating in reverse conduction mode, the RCPS will experience greater conduction losses if the control voltage of the same module is at turn on level. For example, with a BIGT module, if the lower BIGT 504 is operating in reverse conduction mode, the BIGT conduction losses will be higher if the gate voltage applied to the lower BIGT is +15 Volts (turn on level) and compared to −15 Volts (turn off level), in some cases up to 30 percent higher.

To improve the efficiency of the RCPS inverter, a drive circuit incorporating the gate driver 314 may be configured to disable the forward conduction mode operation of the RCPS module depending on the polarity of the current through the module. Referring to the lower BIGT 404 as an example, a drive circuit incorporating the gate driver 314 may be configured to determine the polarity of the current in the lower BIGT. If the current polarity indicates that the lower BIGT is operating in reverse conduction mode, the lower BIGT may be commanded by the drive circuit to disable forward conduction mode, even if the external trigger from the control circuit 316 is commanding the lower BIGT 404 to enable forward conduction mode. In this way, the gate voltage applied to the lower BIGT 404 will be different, e.g. lower, than the stationary on-value when operating in reverse conduction mode, resulting in more efficient operation of the inverter. The gate driver 314 for the upper BIGT 402 may be configured in the same manner.

FIG. 6 is a graph of an exemplary switching scheme that may be employed an inverter, in accordance with embodiments. The switching scheme may be employed in an inverter that uses any suitable type of power switch, including IGBTs, BIGTs, and reverse conducting IGBTs, among others. The diagram of FIG. 6, shows the gate drive signal and resulting currents induced in the power switch module, wherein the power switch module may be the upper or lower BIGT 402 or 404 or the upper or lower IGBT 302 or 304 in combination with the corresponding anti-parallel diode 306 or 308, for example.

The control voltage signal, Vctrl, is represented by the dotted line 604. The dashed line 606 represents the current in the switch module when operating in forward conduction mode. The solid line 608 represents the current in the power switch module when operating in reverse conduction mode. As discussed in relation to FIGS. 3 and 4, the gate drive signal pulses the switch module between the turn on voltage level and the turn off voltage level, to generate the output AC waveform. For example, in the case of an IGBT 302 or 304, the turn on voltage level causes the IGBT 302 or 304 to turn on, and the turn off voltage level causes the IGBT 302 or 304 to turn off. Similarly, in the case if a BIGT 402 or 404, the turn on voltage level enables forward conduction mode operation of the BIGT 402 or 404, and the turn off voltage level disables forward conduction mode operation of the BIGT 402 or 404.

As discussed above in relation to FIG. 5, the drive circuit may also be configured to disable forward conduction mode operation of the power switch module depending on the polarity of the current in the switch module. For example, forward conduction mode operation may be disabled if the polarity of the current indicates that the switch module is operating in reverse conduction mode. For the lower power switch module, a negative current polarity corresponds to current in the direction from the lower rail 312 to the phase output 318. For the upper power switch module, a negative current polarity corresponds to current in the direction from the phase output 318 to the upper rail 310. In both cases, negative current polarity indicates that the switch module is operating in reverse conduction mode. As shown, in FIG. 6, when the polarity of the current in the switch module indicates that the switch module is operating in reverse conduction mode, the gate voltage is maintained at the turn off level, thus disabling forward conduction mode operation of the power switch module. In the case of an IGBT module, maintaining the gate voltage at the turn off level, keeps the IGBT switched off, thus avoiding intra module commutation, for example, between the lower IGBT 302 and the lower diode 308 due to spurious triggering of the upper IGBT 302. In the case of a BIGT switch module 402 or 404, maintaining the gate voltage at the turn off level, disables forward conduction mode operation of the BIGT module and enables the BIGT module to operate more efficiently in reverse conduction mode.

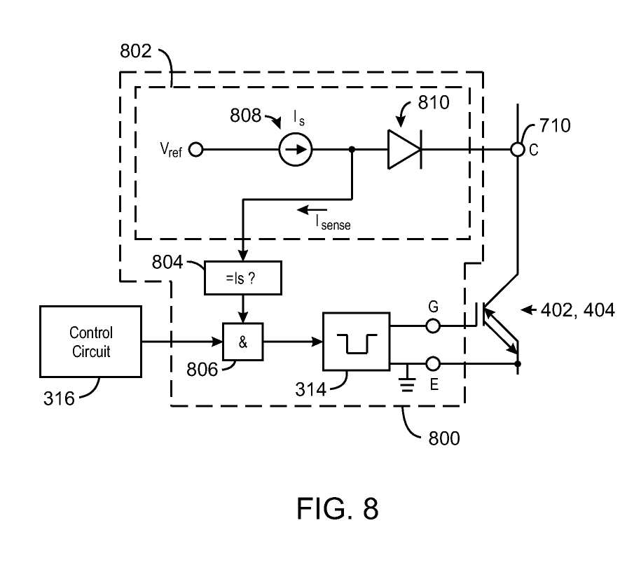

FIG. 6 also shows a change-over phase 610, wherein the power switch module transitions between reverse conduction mode operation and forward conduction mode operation within a single control pulse from the control circuit 316. If the power switch module is operating in reverse conduction mode when the control circuit 316 commands the drive circuit to enable forward conduction mode operation, the gate driver 314 will nevertheless maintain the gate voltage at turn off level, to disable forward conduction mode operation of the switch module. If the drive circuit subsequently detects that the switch module is no longer operating in reverse conduction mode, the drive circuit may then enable forward conduction mode operation of the power switch module in accordance with the signal from the control circuit 316. In embodiments, the drive circuit may be configured to detect the reverse conduction mode operation of the switch module within the interlock time employed by the control circuit 316. Exemplary drive circuits for implementing the switching scheme of FIG. 6 are described below in reference to FIGS. 7 and 8.

FIG. 7 is a block diagram of an example of a drive circuit in accordance with embodiments. The exemplary drive circuit shown in FIG. 7 can be used to implement the switching scheme shown in FIG. 5. Although FIG. 7 shows a drive circuit 700 for a BIGT module, it will be appreciated that the drive circuit shown in FIG. 7 can also be used with any other type of power switch module, such as an IGBT, reverse conducting IGBT, and the like. Further, although one drive circuit 700 is shown, it will be appreciated that each switch module of an inverter may include its own dedicated drive circuit 700.

As shown in FIG. 7, the drive circuit 700 may include a current sensing circuit 702, comparator 704, AND-gate 706, and a gate driver 314. The current sensing circuit 702 is configured to estimate the collector-emitter current, Ice, through the BIGT 402 or 404. The BIGT 402 or 404 may be coupled to a set of terminals, including a collector terminal 710, gate terminal 712, and emitter terminals 714 and 716. The first emitter terminal 714 is referred to as a control terminal and enables the gate driver 314 to be coupled across the gate and the emitter of the BIGT. The second emitter terminal 716 is referred to as a power terminal and enables the BIGT emitter to be coupled to the rest of the circuitry in the inverter, for example, either the lower rail 312 or the phase output 318 (FIG. 4). Between the first emitter terminal 714 and the second emitter terminal 716 is a conductor with a parasitic inductance, as indicated by an inductor 718.

In an embodiment, the current sensing circuit 702 includes a voltage sensor 720 for measuring the voltage between the first emitter terminal 714 and the second emitter terminal 716, and an integrator 722 to determine an estimate of the collector-emitter current based on the measured voltage. Due to the parasitic inductance 718, the voltage between the first emitter terminal 714 and the second emitter terminal 716 may be approximately equal to the instantaneous rate of change in the emitter-collector current, dIce/dt. Thus, the emitter-collector current can be estimated by integrating the voltage measured using the integrator 722.

The output of the integrator 722 is an estimate of the collector-emitter current in the BIGT 402 or 404. The output of the integrator 722 can be coupled to the comparator 704, which may determine whether the estimated current is greater than a reference current, Iref. In an embodiment, the reference current, Iref, may be zero, so that the output of the comparator 704 is directly related to the polarity of the estimated collector-emitter current. For example, if the estimated collector-emitter current is positive, meaning that the BIGT 402 or 404 is operating in forward conduction mode, the output of the comparator 704 may be set to logical one. If the estimated collector-emitter current is negative, meaning that the BIGT 402 or 404 is operating in reverse conduction mode, the output of the comparator 704 may be set to logical zero.

The output of the comparator 704 and the output of the control circuit 316 may be coupled to the input of the AND-gate 706. The output of the AND-gate is coupled to the input of the gate driver 314. Accordingly, the gate driver 314 will receive a command to enable forward conduction operation of the BIGT 402 or 404 if the control circuit 316 is commanding the BIGT 402 or 404 to turn on and the estimated collector-emitter current in the BIGT 402 or 404 indicates the that the BIGT 402 or 404 is not operating in reverse conduction mode.

As noted above, the same drive circuit could be used, for example, in an IGBT inverter, in which case, the BIGT 402 or 404 would be replaced by a power switch module that includes an IGBT 302 or 304 and anti-parallel diode 306 or 308. Similar to the BIGT inverter, the gate driver 314 will receive a command to turn on the IGBT 302 or 304 if the control circuit 316 is commanding the IGBT 302 or 304 to turn on and the estimate collector-emitter current in the IGBT switch module indicates the that diode 306 or 308 of the switch module is not conducting.

FIG. 8 is a block diagram of a drive circuit in accordance with embodiments. The exemplary drive circuit shown in FIG. 8 can be use to implement the switching scheme shown in FIG. 5. Further, although a BIGT 402 or 404 is shown, it will be appreciated that the drive circuit shown in FIG. 8 can also be used with any type of switch module, such as an IGBT, reverse conducting IGBT, and the like. Further, although one drive circuit 800 is shown, it will be appreciated that each switch module of an inverter may include its own dedicated drive circuit 800.

As shown in FIG. 8, the drive circuit 800 may include a voltage sensing circuit 802, comparator 804, AND-gate 806, and a gate driver 314. The voltage sensing circuit 802 is configured to detect the voltage level across the power terminals, Vce, across the BIGT 402 or 404. At least two different voltage levels can be detected. In some embodiments, the voltage sensor can include a current source 808. The output of the current source 808 may be coupled to a collector terminal 710 of the BIGT 402 or 404 through a diode 810 and also to the input of the comparator 804. The input to the current source may be coupled to a reference voltage, Vref, which may be approximately 0 Volts. In some embodiments, the voltage sensor can include a voltage divider with a following comparator or analog digital converter stage.

Depending on the voltage to emitter at the collector terminal 710, the current from the current source 808 will follow a path through the diode 810 to the collector terminal 710 or to the comparator 804. The current input to the comparator is referred to as the sense current, Isense. When the BIGT 402 or 404 is operating in reverse conduction mode, the voltage at the collector terminal 710, Vc, will be negative. The negative voltage at the collector terminal 710 forward biases the diode 810 so that the source current, Is, follows a path through the diode 810 to the collector terminal 710 and Isense will be at or close to zero. When the BIGT 402 or 404 is operating in forward conduction mode or blocking mode, the voltage at the collector terminal 710, Vc, will be positive. The positive voltage at the collector terminal 710 negatively biases the diode 810 such that the source current, Is, is conducted to the comparator 804 and Isense equals a non-zero number approximately equal to the source current. To summarize, the input to the comparator will be less than the source current, Is, when operating in reverse conduction mode and approximately equal to the source current when operating in forward conduction mode or blocking mode.

The comparator 804 may compare the input current to the source current, Is, which may be a known value that can be determined based on the design considerations for a particular circuit. If the input current equals the source current (forward conduction mode), the comparator 804 may enable the forward conduction mode operation by, for example, sending a logic one to the AND-gate. If the input current is less than the source current (reverse conduction mode), the comparator 804 may disable the forward conduction mode operation by, for example, sending a logic zero to the AND-gate. The output of the control circuit 316 is also coupled to the input of the AND-gate 706 or 806. The output of the AND-gate is coupled to the input of the gate driver 314. Accordingly, the gate driver 314 will receive a command to activate forward conduction mode operation of the BIGT 402 or 404 if the control circuit 316 is commanding the BIGT 402 or 404 to turn on and the detected collector-emitter voltage across the BIGT 402 or 404 indicates the that the BIGT 402 or 404 is not operating in reverse conduction mode.

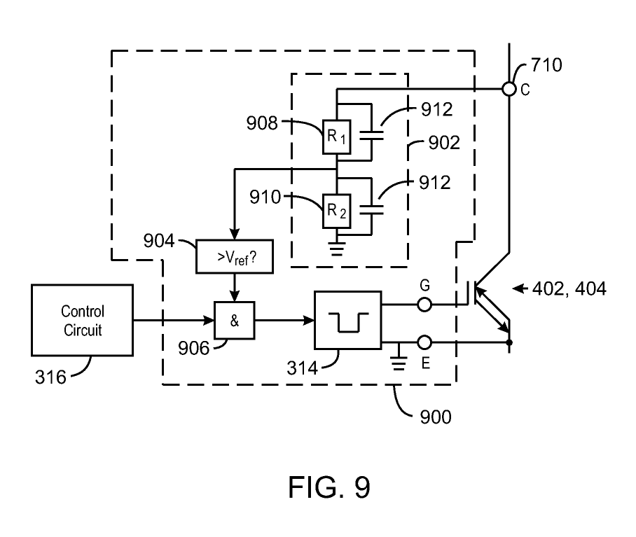

FIG. 9 is a block diagram of a drive circuit in accordance with embodiments. The exemplary drive circuit shown in FIG. 9 can be use to implement the switching scheme shown in FIG. 5. Further, although a BIGT 402 or 404 is shown, it will be appreciated that the drive circuit shown in FIG. 9 can also be used with any type of switch module, such as an IGBT, reverse conducting IGBT, and the like. Further, although one drive circuit 900 is shown, it will be appreciated that each switch module of an inverter may include its own dedicated drive circuit 900.

As shown in FIG. 9, the drive circuit 900 may include a voltage divider 902, comparator 904, AND-gate 906, and a gate driver 314. The voltage divider 902 is configured to detect the voltage level across the power terminals. Vce, across the BIGT 402 or 404. At least two different voltage levels can be detected. In some embodiments, the voltage divider 902 includes a pair of resistors, R1 908 and R2 910, coupled in series. In an embodiment, capacitors 912 can be disposed in parallel with the resistors 908 and 910 to optimize the dynamic response of the voltage divider 902. The output of the voltage divider 902 may be coupled to the input of a comparator 904 that compares the voltage level across the lower resistor R2 910 to a voltage reference, which may be approximately 0 Volts. When the BIGT 402 or 404 is operating in reverse conduction mode, the voltage at the collector terminal 710, Vc, will be negative and the voltage level across the lower resistor R2 910 will be lower than the voltage reference. When the BIGT 402 or 404 is operating in forward conduction mode or blocking mode, the voltage at the collector terminal 710, Vc, will be positive and the voltage level across the lower resistor R2 910 will be greater than the voltage reference.

If the voltage level across the lower resistor R2 910 is greater than the voltage reference, the comparator 804 may enable the forward conduction mode operation by, for example, sending a logic one to the AND-gate. If the voltage level across the lower resistor R2 910 is lower than the voltage reference (reverse conduction mode), the comparator 804 may disable the forward conduction mode operation by, for example, sending a logic zero to the AND-gate. The output of the control circuit 316 is also coupled to the input of the AND-gate 906. The output of the AND-gate 906 is coupled to the input of the gate driver 314. Accordingly, the gate driver 314 will receive a command to activate forward conduction mode operation of the BIGT 402 or 404 if the control circuit 316 is commanding the BIGT 402 or 404 to turn on and the detected collector-emitter voltage across the BIGT 402 or 404 indicates the that the BIGT 402 or 404 is not operating in reverse conduction mode.

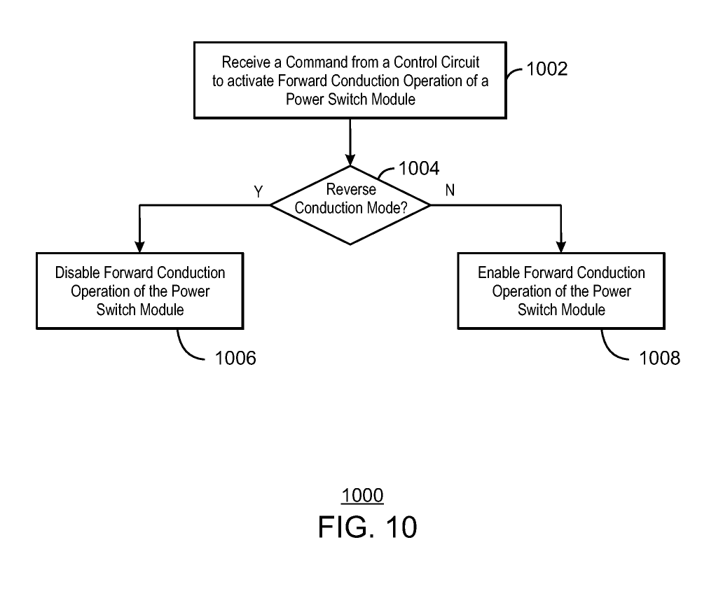

FIG. 10 is a process flow diagram summarizing a method of operating an inverter module in accordance with embodiments. The method 1000 may implemented by a drive circuit coupled to a power switch module, such as the drive circuits 700 and 800 of FIGS. 7 and 8. At block 1002, a command to enable a forward conduction mode operation of a switch module may be received from a control circuit.

At block 1004, a determination may be made regarding whether the power switch module is operating in reverse conduction mode. In embodiments, determining whether the power switch module is operating in reverse conduction mode includes determining a polarity of current through the power terminals of the power switch module. For example, determining whether the power switch module is operating in reverse conduction mode may include measuring a voltage across a parasitic inductance between a first emitter terminal and a second emitter terminal and integrating the voltage to estimate the current through the emitter terminal. In another example, determining whether the power switch module is operating in reverse conduction mode includes detecting the voltage level across the power terminals of the power switch module.

If, at block 1004, the switch module is operating in reverse conduction mode, the process flow may advance to block 1006 and the forward conduction mode operation of the power switch module may be disabled. Accordingly, forward conduction mode operation of the switch module is disabled when the polarity of the current is negative in a direction from the collector terminal to the emitter terminal.

If, at block 1004, the switch module is not operating in reverse conduction mode, the process flow may advance to block 1008 and the forward conduction mode operation of the power switch module may be enabled. Accordingly, the forward conduction mode operation of the power switch module will only be activated if the control circuit is commanding the activation of the forward conduction mode operation and the forward conduction mode operation is not disabled.

It is to be understood that the above description is intended to be illustrative, and not restrictive. For example, other means of sensing current in the switch could be employed, such as a shunt or a giant magnetoresistive device. For example, the above-described embodiments (and/or aspects thereof) may be used in combination with each other. In addition, many modifications may be made to adapt a particular situation or material to the teachings of the invention without departing from its scope. While the dimensions and types of materials described herein are intended to illustrate embodiments of the invention, they are by no means limiting and are exemplary in nature. Other embodiments may be apparent upon reviewing the above description. The scope of the invention should, therefore, be determined with reference to the appended claims, along with the full scope of equivalents to which such claims are entitled.

In the appended claims, the terms “including” and “in which” are used as the plain-English equivalents of the respective terms “comprising” and “wherein.” Moreover, in the following claims, the terms “first,” “second,” “3^{rd},” “upper,” “lower,” “bottom,” “top,” “up,” “down,” etc. are used merely as labels, and are not intended to impose numerical or positional requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

As used herein, an element or step recited in the singular and proceeded with the word “a” or “an” should be understood as not excluding plural of said elements or steps, unless such exclusion is explicitly stated. Furthermore, references to “one embodiment” of the invention are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional such elements not having that property.

Since certain changes may be made in the above-described control method, without departing from the spirit and scope of the invention herein involved, it is intended that all of the subject matter of the above description or shown in the accompanying drawings shall be interpreted merely as examples illustrating the inventive concept herein and shall not be construed as limiting the invention.

1. A power electronic module comprising:
a power switch module; and
a drive circuit operatively coupled to the power switch module and configured to enable and disable a forward conduction mode operation of the power switch module;
wherein the drive circuit disables forward conduction mode operation of the power switch module when the power switch module is operating in reverse conduction mode.

2. The power electronic module of claim 1, wherein the power switch module comprises an insulated gate bipolar transistor (IGBT) and a diode disposed in anti-parallel with the IGBT.

3. The power electronic module of claim 1, wherein the power switch module comprises a reverse conductive power switch that provides the functionality of an IGBT and a diode disposed in anti-parallel with the IGBT.

4. The power electronic module of claim 1, wherein the drive circuit is configured to determine whether the power switch module is operating in reverse conduction mode within an interlock time.

5. The power electronic module of claim 1, wherein the drive circuit comprises a current sense circuitry configured to determine a polarity of the current flowing through the power terminals of the power switch module, wherein determining whether the power switch module is operating in reverse conduction mode comprises determining the polarity of the power switch module current.

6. The power electronic module of claim 5, wherein the current sense circuitry provides a current estimation by measuring a voltage across a parasitic inductance disposed between a control or sensing terminal and a power terminal.

7. The power electronic module of claim 5, wherein the drive circuit comprises an AND-gate configured to receive:
a first input from a control circuit configured to activate forward conduction mode operation of the power switch module; and
a second input configured to enable or disable forward conduction mode operation of the power switch module based on an output of the current sense circuitry, wherein an output of the AND-gate is coupled to an input of a gate driver of the power switch module.

8. The power electronic module of claim 5, wherein the voltage sense circuitry comprises a current source coupled to a collector terminal of the power switch module through a diode, wherein an output of the voltage sense circuitry is responsive to a voltage of the collector terminal.

9. The power electronic module of claim 1, wherein the drive circuit comprises a voltage sense circuitry configured to determine the voltage polarity across the power terminals of the power switch module, wherein determining whether the power switch module is operating in reverse conduction mode comprises determining the polarity of the voltage across the power terminals of the power switch module.

10. The power electronic module of claim 9, wherein the voltage sense circuitry comprises a voltage divider circuit with a following comparator or analog digital converter.

11. The power electronic module of claim 9, wherein the drive circuit comprises an AND-gate configured to receive:
a first input from a control circuit configured to activate forward conduction mode operation of the power switch module; and
a second input configured to enable or disable forward conduction mode operation of the power switch module based on an output of the voltage sense circuitry, wherein an output of the AND-gate is coupled to an input of a gate driver of the power switch module.

12. A power system for a vehicle comprising:
a first power switch module coupled to a DC rail voltage and configured to switch on and off in an alternation with a second switch module to produce an output AC waveform;
a drive circuit operatively coupled to the first switch module and configured to enable and disable a forward conduction mode operation of the first switch module;
wherein the drive circuit disables forward conduction mode operation of the first power switch module when the first power switch module is operating in reverse conduction mode.

13. The power system of claim 12, wherein the first switch module comprises an insulated gate bipolar transistor (IGBT) and a diode disposed in anti-parallel with the IGBT.

14. The power system of claim 12, wherein the first power switch module comprises a reverse conductive power switch that provides the functionality of an IGBT and a diode disposed in anti-parallel with the IGBT.

15. The power system of claim 12, wherein a control circuit coupled to the drive circuit imposes an interlock time between switching off the second power switch module and switching on the first power switch module, and the drive circuit determines whether the first power switch module is operating in reverse conduction mode within the interlock time.

16. The power system of claim 12, wherein the drive circuit comprises a current sense circuitry configured to determine a polarity of the current flowing through the first power switch module, wherein determining whether the first power switch module is operating in reverse conduction mode comprises determining the polarity of the power switch module current.

17. The power system of claim 16, wherein the current sense circuitry provides a current estimation by measuring a voltage across a parasitic inductance disposed between a control terminal and a power terminal of the power electronic module.

18. The power system of claim 16, wherein the drive circuit comprises a voltage sense circuitry configured to determine the voltage polarity across the power terminals of the power switch module, wherein determining whether the power switch module is operating in reverse conduction mode comprises determining the polarity of the voltage across the power terminals of the power switch module.

19. The power system of claim 18, wherein the voltage sense circuitry comprises a current source coupled to a collector terminal of the first power switch module through a diode, wherein an output of the voltage sense circuitry is responsive to a voltage of the collector terminal.

20. The power electronic module of claim 18, wherein the voltage sense circuitry comprises a voltage divider circuit with a following comparator or analog digital converter.

21. A method, comprising:
receiving a command from a control circuit to activate a forward conduction mode operation of a power switch module;
determining whether the power switch module is operating in reverse conduction mode;
if the power switch module is operating in reverse conduction mode, disabling forward conduction mode operation of the power switch module; and
if the power switch module is not operating in reverse conduction mode, enabling forward conduction mode operation of the power switch module.

22. The method of claim 21, wherein determining whether the power switch module is operating in reverse conduction mode comprises determining a polarity of current through the power terminals of the power switch module.

23. The method of claim 22, wherein forward conduction mode operation of the power switch module is disabled when the current through the power switch module is conducted in reverse direction.

24. The method of claim 21, wherein determining whether the power switch module is operating in reverse conduction mode comprises determining a polarity of voltage across the power terminals of the power switch module.

25. The method of claim 21, wherein determining whether the power switch module is operating in reverse conduction mode comprises:
measuring a voltage across a parasitic inductance between a first emitter terminal and a second emitter terminal; and
integrating the voltage to estimate the current through the collector terminal and emitter terminal of the power switch module.

26. The method of claim 21, wherein determining whether the switch module is operating in reverse conduction mode comprises receiving a sense current from a current source coupled in series with the a collector terminal of the switch module, wherein the sense current is responsive to a voltage of the collector terminal.

27. The method of claim 21, wherein determining whether the switch module is operating in reverse conduction mode comprises a voltage divider circuit with a following comparator or analog digital converter.
